(19) United States
(12) Patent Application Publication
(10) Pub. No.: US 2009/0068450 A1
(43) Pub. Date: Mar. 12, 2009

(54) Method and Apparatus for Multi-Cathode PVD Coating and Substrate with PVD Coating

(76) Inventors: Wolf-Dieter Muenz, Wien (AT); Dieter Hofmann, Gelnhausen (DE); Stefan Kunkel, Biebergemund (DE); Juergen Mangold, Rothhausen (DE); Hans Schuessler, Schiffweiler (DE)

Correspondence Address: PROPAT, L.L.C., 425-C SOUTH SHARON AMITY ROAD, CHARLOTTE, NC, 28211-2841, US

(21) Appl. No.: 11/995,123

(22) PCT Filed: Jul. 11, 2006
(86) PCT No.: PCT/EP2006/006768

§ 371 Date: May 28, 2008

(30) Foreign Application Priority Data
Jul. 15, 2005 (DE) 102005033769.4

(51) Int. Cl. B32B 15/04; C23C 14/35; C23C 14/34; B32B 9/00; C23C 14/42; B32B 9/04

(52) U.S. Cl. 428/336; 204/192.12; 204/192.15; 204/298.06; 428/411.1; 428/457; 428/698

(57) ABSTRACT

The invention relates to a method for operating a multi-cathode-PVD-coating system. According to the invention, one part of the cathodes operates after the high power impulse cathodic sputtering which is assisted by magnetic fields and the remainder operates after the direct current magnetic field assisted cathodic sputtering. The high power impulse cathodic sputtering which is assisted by magnetic fields is used as a source of multi-ionised metal ions during the ion-assisted in vacuo pre-treatment of substrates, whilst both types of cathodic sputtering are always used simultaneously during coating and whilst both types of cathodes are connected to different materials.

The invention relates to a method and an apparatus for multi-cathode PVD coating of substrates.

Cathode sputtering has become increasingly important in the field of PVD coating. Both the wide range of materials and the reproducibility of the coating process have contributed to this development. In addition to monolithically formed layer structures, multiple layer architectures have become more important in the last decade. Particularly in the field of nano-scaled multiple layers and so-called superlattices, excellent layer characteristics are achieved with respect to wear resistance, oxidation resistance and corrosion resistance.

In particular, it has been possible to considerably increase the hardness of the condensed nanocrystalline layers, specifically up to about 50% of diamond hardness, that is to say up to about 50 GPa [1].

In general, these novel super hard layers have enormous compressive stresses, to be precise up to more than −7 GPa. For this reason, the adhesive strength of the condensed layers on the substrates, which are normally composed of steel, hard metal or materials prepared in advance by means of electrochemical layers, is of major importance.

During the course of development of cathode sputtering, it has been found that the adhesive strength of super hard layer systems such as these is limited if the substrates have been pretreated only with argon ions as in-vacuo cleaning.

In addition to multilayer intermediate layers whose production processes are complex, mechanical pre-treatments [2] are also carried out in order to reduce the compressive stress gradient between the relatively soft substrate and the PVD layer.

Metal-ion pre-treatment before the actual coating process reduces the compressive stresses. This method has been developed by means of cathodic arc discharge [3] for coating technology purposes.

A plasma which contains a high concentration of metal ions with one or more charges is formed in a cathodic arc discharge [4 ].

Basic experiments have shown [5, 6] that the combined pre-treatment of the substrates with metal ions from a cathodic arc discharge results in subsequent layers, which are deposited with an unbalanced magnetron (UBM), having point epitaxial layer growth which results in increased adhesion of the layers [7].

Empirically, this relationship has been known for a relatively long time [8, 9, 10] and is used industrially in the so-called arc bond sputter process [11]. This method has the disadvantage that the macroparticles which are typical of cathodic arc discharges, so-called droplets [12], are created during the metal-ion pre-treatment and lead to undesirable inhomogeneities in the layer. Inhomogeneities such as these also disadvantageously influence the subsequent coating process, which is droplet-free per se, by means of UBM [13].

EP 1260603 A2 discloses a PVD method for coating substrates, in which the substrate is pretreated in the plasma of a pulsed magnetic-field-assisted cathode sputtering process (HIPIMS). A magnetron cathode is used to assist the magnetic field during the pre-treatment. After the pre-treatment, a further coating is produced, for example by means of UBM cathode sputtering. Identical cathodes and identical magnetic-field arrangements are used for the pre-treatment and the coating.

EP 0521045 B1 discloses a method for ion plating using a first and a second magnetron, each of which has an inner pole and an outer annular pole of opposite polarity. The magnetrons are arranged such that the outer annular pole of one magnetron and the outer annular pole of the second or further magnetron are arranged adjacent to the respective other one, and are of opposite polarity. One of the magnetrons is operated in the unbalanced state.

WO 98/40532 discloses a method and an apparatus with magnetically assisted cathode sputtering, with the cathode being operated using high-power pulses (HIPIMS).

The object of the present invention is to provide a method and an apparatus for PVD coating of substrates, in which the occurrence of macroparticles, which lead to undesirable inhomogeneities in the coating, is largely avoided and high-hardness multiple layers with good adhesion on the substrate are produced.

According to the method, this object is achieved by the following steps:
(a) pre-treatment of the substrate surface by high-power impulse magnetron cathode sputtering (HIPIMS),
(b) coating by means of unbalanced magnetron cathode sputtering (UBM),
(c) coating by means of HIPIMS, and
(d) repetition of steps (b) and (c) one or more times.

In an improvement of the method, step (a) is carried out with a cathode target composed of metal in a gas atmosphere at a pressure of less than or equal to 1·10⁻² mbar and with a substrate potential of −500 to −2000 V, with the substrate surface being etched and implanted with metal ions that have been positively charged one or more times.

A further refinement of the method results from Patent claims 3 to 15.

The apparatus according to the invention for multi-cathode PVD coating is equipped with one or more process chambers, with each process chamber having at least one HIPIMS cathode and at least one UBM cathode.

A further refinement of the apparatus results from Patent claims 17 to 20.

The substrate according to the invention with PVD coating comprises an implantation layer, which is produced by HIPIMS in the substrate surface, and one or more double layers, which are deposited by means of UBM and HIPIMS.

The development of the substrate is described in Patent claims 22 to 30.

The invention achieves the advantage that the metal-ion etching during the pre-treatment is carried out by means of HIPIMS, therefore greatly reducing the creation of macroparticles. The multiple layer architecture is formed by simultaneous use of UBM and HIPIMS.

The specific HIPIMS cathode sputtering method was initially used solely for deposition of PVD layers [14]. However, consideration of HIPIMS for metal-ion etching as a substrate pre-treatment strictly combined with subsequent coating exclusively using the unbalanced magnetron was first demonstrated briefly [17]. However, in this method, the UBM and HIPIMS cathodes are not operated simultaneously.

The invention will be explained in more detail in the following text with reference to the drawings, in which:

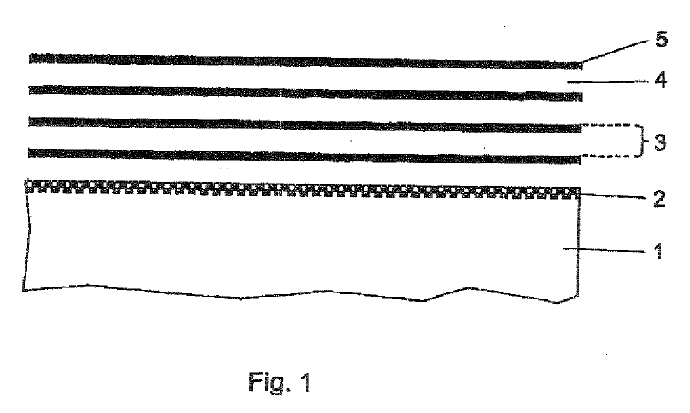

FIG. 1 shows a schematic section through a layer system of a substrate according to the invention;

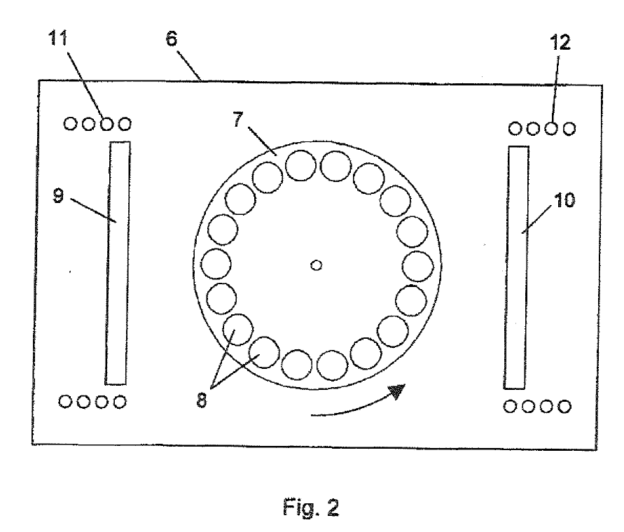

FIG. 2 shows a schematic view of a first embodiment of the apparatus according to the invention;

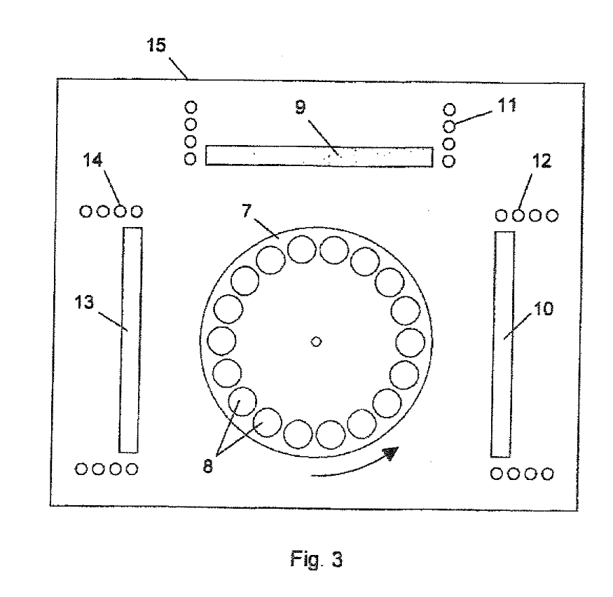

FIG. 3 shows a schematic view of a second embodiment of the apparatus according to the invention; and

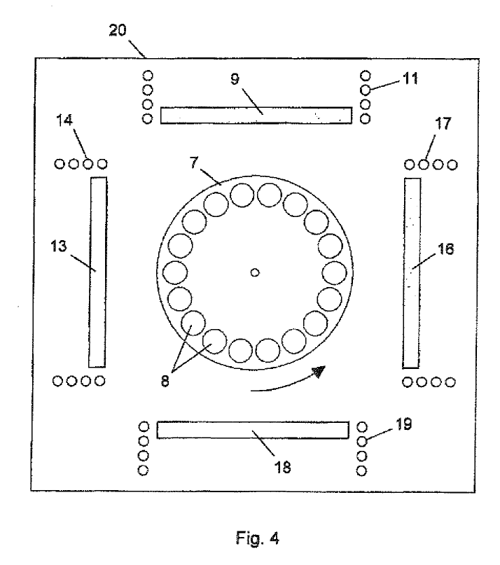

FIG. 4 shows a schematic view of a third embodiment of the apparatus according to the invention;

The method is distinguished in that a plasma is produced and in that, in a similar manner to that with the cathodic arc discharge, metal ions that are multiple charged are generated, but no macroparticles (droplets) are produced.

Metal-ion etching is carried out before coating using the HIPIMS method. Furthermore, however, the HIPIMS method is used simultaneously with the unbalanced magnetron (UBM) for coating.

The invention does not just consist in the simultaneous use of the two procedures during coating but also in the fact that the coating materials for HIPIMS and UBM are fundamentally different. For example, materials such as Ti, Cr, Zr, V, Nb, Mo, Ta, W or Al are used for pre-treatment in the HIPIMS method. During the coating process, these materials are deposited as nitrides, carbides, carbon-nitrides, oxides or oxynitrides. With UBM, materials are deposited which are not identical to the materials deposited with the HIPIMS. For example, while CrN can be deposited with HIPIMS, TiNx or, for example, NbN is deposited simultaneously with the UBM. This results in layer systems with layers of the type shown in FIG. 1.

UBM can also be used to sputter multi-component materials such as TiAl, TiAlY, CrAl, ZrAl or pure graphite, so that layer sequences such as CrN/TiAlN or TiN/CrAlN or W/C are created. One particularly preferred deposition condition is the production of layers based on the superlattice architecture [1, 18]. In this case, the coating parameters must be chosen such that the thickness of the double layer, for example VN/TiAlN, is approximately 3-5 nm.

In order to produce these novel layers, specific cathode arrangements are required in the PVD systems to be used. FIGS. 2 to 4 show three basic configurations of the process chambers according to the invention.

### EXAMPLE 1

The first embodiment of a process chamber 6, illustrated in FIG. 2, contains two coating sources, that is to say an HIPIMS cathode 9 and a UBM cathode 10, and this is preferably used in small systems. 500 mm long linear cathodes are used in a system with a vacuum tank whose diameter is 700 mm and whose height is 700 mm (internal dimension). By way of example, the HIPIMS cathode 9 is equipped with a tungsten target material, and the UBM cathode 10 is equipped with graphite as the target material. A rotating substrate support 7 which is arranged between the cathodes has a diameter of 400 mm, and can be fitted over a height of 400 mm. For example, 10 rotating planets with a diameter of 50 mm are used on the substrate support 7 and are fitted with clean substrates 8, which have been precleaned for vacuum coating. The substrates 8 may be components for passenger vehicles, fittings, attachments and the like which, for example, are manufactured from the material 100Cr6.

Once the system has been loaded, the chamber door is closed and the chamber pressure is reduced from atmospheric pressure to a pressure of <5·10⁻⁵ mbar by pumping out the vacuum chamber. Argon is then let into the chamber until a pressure of 2·10⁻³ mbar is reached.

The HIPIMS cathode 9 is equipped with a solenoid electromagnet 11. The UBM cathode 10 is likewise equipped with a solenoid electromagnet 12.

A tungsten implantation layer is produced by operation of the HIPIMS cathode 9 with simultaneous application of a substrate potential of −1000 V, by means of a combined ion-etching process and coating process.

Argon and acetylene are then introduced into the process chamber, and a pressure of 5·10⁻³ mbar is set. At the same time, the negative substrate potential is reduced to −100 V, and the UBM cathode 10 is switched on.

A multiple double-layer structure composed of W/C, as shown in FIG. 1, is applied by simultaneous operation of the HIPIMS cathode 9 and the UBM cathode 10.

### EXAMPLE 2

The second embodiment of a process chamber 15, shown in FIG. 3, contains three coating sources, that is to say an HIPIMS cathode 9 and two UBM cathodes 10, 13, and is preferably used for Cluster-Inline systems. 1350 mm long linear cathodes 9, 10, 13 are used in the process chambers in the Cluster-Inline system of the DeQoTec type from the company Systec System- und Anlagenbau GmbH & Co. KG., Karlstadt, Germany, with chamber internal dimensions of 930×1720×550 mm (length×height×width). By way of example, the HIPIMS cathode 9 is equipped with titanium as the target material, and the two UBM cathodes 10, 13 are equipped with graphite as the target material. The rotating substrate support 7 which is arranged between the cathodes has a diameter of 300 mm, and can be fitted over a height of 1000 mm. By way of example, eight rotating planets of 50 mm are used on the substrate support 7 and are fitted with clean substrates 8 or components composed of the material 100Cr6, which have been precleaned for vacuum coating. By way of example, this material is used for ball bearings.

The HIPIMS cathode 9 is equipped with a solenoid electromagnet 11, and the two UBM cathodes 10, 13 are equipped with solenoid electromagnets 12, 14.

Once the inlet/outlet charging chamber of the system has been loaded, the chamber door is closed and the chamber pressure is reduced from atmospheric pressure to a pressure of <5·10⁻⁵ mbar by pumping out the vacuum chamber. The openings which are located between a central chamber and the process chambers are in this case closed by sealing plates. All the sealing plates, which are also fitted with the brackets, on which the substrate supports 8 are inserted, are then opened via a central drive mechanism which is located in the central chamber, and the substrate supports are moved into the central chamber, are then positioned in front of the next process chamber by a 90° rotary movement, and are then moved into this chamber. When the substrate support reaches the final position in the process chamber accommodating it, the connection of the process chamber to the central chamber is once again closed at the same time, by means of the sealing plates.

The cathode arrangement described above is located in the process chamber adjacent to the inlet/outlet charging chamber. Only argon is introduced into this process chamber, until a pressure of 3·10⁻³ mbar is reached.

A titanium implantation layer is produced by operation of the HIPIMS cathode 9 with simultaneous application of a substrate potential of −1100 V, by means of a simultaneous ion-etching process and coating process.

Argon and acetylene are then introduced, and a pressure of 4·10⁻³ mbar is set. At the same time, the negative substrate potential is reduced to −80 V, and the two UBM cathodes 10, 13 are switched on.

A multilayer coating with TiC/C is applied, with the layer architecture shown in FIG. 1, by simultaneous operation of the HIPIMS cathode 9 and the UBM cathodes 10, 13.

This layer has a coefficient of friction μ of less than 0.2.

### EXAMPLE 3

The third embodiment of a process chamber 20 shown in FIG. 4 contains four coating sources, that is to say two HIPIMS cathodes 9, 16 and two UBM cathodes 13, 18, and is preferably used for medium-size and large single-chamber systems. 950 mm long linear cathodes are used in a system of the Z1200 type from the company Systec System- und Anlagenbau GmbH & Co. KG., Karlstadt, Germany, with a square vacuum tank with internal dimensions of 1500 mm×1500 mm (length×width) and a tank height of 1500 mm. The two HIPIMS cathodes 9, 16 are equipped with chromium as the target material, and the UBM cathodes 13, 18 are equipped with Ti/Al (50/50 by atomic percent) as the target material. A rotating substrate support 7 is located in a central position between the cathodes, has a diameter of 400 mm, and can be fitted over a height of 600 mm. By way of example, ten rotating planets with a diameter of 150 mm are used on the substrate support, and are fitted with clean substrates 8 or components, which have been precleaned for vacuum coating, composed of the material 100Cr6.

The HIPIMS cathodes 9, 16 are equipped with solenoid electromagnets 11, 17, and the two UBM cathodes 13, 18 are equipped with solenoid electromagnets 14, 19.

Once the system has been loaded, the chamber door is closed and the chamber pressure is reduced from atmospheric pressure to a pressure of <3·10⁻⁵ mbar by pumping out the vacuum chamber. Argon is then introduced into the chamber until a pressure of 2.5·10⁻³ mbar is reached.

An ion-etching process and a coating process are carried out simultaneously by operation of the HIPIMS cathodes 9, 16 with a substrate potential of −1200 V being applied at the same time, resulting in the production of a chromium implantation layer.

Argon and nitrogen are then introduced, and a pressure of 7·10⁻³ mbar is set. At the same time, the negative substrate potential is reduced to −75 V, and the two UBM cathodes 13, 18 are additionally switched on.

A multilayer coating composed of CrN/TiAlN with a double-layer structure as shown in FIG. 1 is produced by simultaneous operation of the two HIPIMS cathodes 9, 16 and the UBM cathodes 13, 18.

In order to optimize the hardness of the resultant layers, the aim is to produce a layer thickness of 3 to 4 nm of the CrN/TiAlN double layers. The resultant layer hardness is about 48 GPa.

The PVD coating is carried out using materials as shown in the following table:

| Implantation | | | |
|---|---|---|---|
| layer | HIPIMS layer | UBM layer | Layer type |
| Ti | TiN | TiAlN | TiN/TiAlN |
| Cr | CrN | TiAlN | CrN/TiAlN |
| Ti | TiN | NbN | TiN/NbN |
| W | W | C | W/C |
| Ta | Ta | C | Ta/C |
| Ti | Ti | C | Ti/C |
| V | V | TiAlN | V/TiAlN |
| Cr | CrN | NbN | CrN/NbN |

The invention provides a method for operation of a multi-cathode PVD coating process, based on the HIPIMS and UBM cathode sputtering variants. The cathodes are operated in the HIPIMS mode for substrate pre-treatment, while the coating is carried out by operating the cathodes simultaneously in the HIPIMS mode and in the UBM mode.

In this case, different target materials are preferably used in the HIPIMS mode and in the UBM mode.

The layer thicknesses of the material double layers are preferably in the range of 3 to 5 nm, and the superlattice effect occurs for super hard layers, with a plastic hardness of >40 GPa.

The distance between the individual cathode and the substrates is not more than 75 cm.

The magnetic fields of the individual cathodes are largely magnetically coupled by means of the solenoid electromagnets.

By means of the solenoid electromagnets with which the cathodes are equipped the unbalance effect is being produced in the cathode plasma The magnetron cathodes are equipped with balanced permanent magnets. By way of example, the permanent magnet materials are NdFeB or SmCo.

The magnetic-field-assisted high-power impulse magnetron cathode sputtering (HIPIMS) is carried out in the following discharge conditions. The pulses which are supplied to the target that is mounted on the HIPIMS cathode typically have power densities of 800 to 3000 WCm⁻², with pulse lengths of 50 to 250 μs and pulse intervals of 20 to 200 ms. The peak voltages could be up to −1200 V. The mean power density is kept in the region of 10 Wcm⁻². In consequence, the mean power density of HIPIMS is comparable to the power density for direct-current UBM, which is likewise around 8 to 10 Wcm⁻².

### REFERENCES

[1] Industrial scale manufactured superlattice hard PVD coatings W. D. Münz, D. B. Lewis, P. E. Hovsepian, C. Schönjahn, A. Ehiasarian, I. J. Smith, Surface Engineering. 2001; vol. 17(1), pp. 15-27
[2] H. K. Tönshoff, C. Blawit, “Influence of Surface Integrity on Performance of Coated Cutting Tools”, Thin Solid Films, pp. 308/309 [1997 (345-350)]
[3] Handbook of Vacuum Arc Science and Technology, by Raymond L. Boxman, David Sanders and Philip J. Martin, (1996), Noyes ISBN 0-8155-1375-5
[4] I. G. Brown, F. Feinberg and J. E. Galvin, J. Appl. Phys. 63 (1988) p. 4889
[5] Dissertation Sheffield Hallham University, Cornelia Schönjahn, February 2001
[6] Optimization of in situ substrate surface treatment in a cathodic arc plasma: A study by TEM and plasma diagnostics C. Schönjahn, A. P. Ehiasarian, D. B. Lewis, R. New, W. D. Münz, R. D. Twesten, I. Petrov, Journal of Vacuum Science & Technology A: Vacuum, Surfaces, and Films. July-August 2001; vol. 19(4) pt. 1-2, pp. 1415-20
[7] B. Window and S. Savides, J. Vac. Sci. Technol. A4 (1986)
[8] H. Wesemeyer, Patent application, Arc/Magnetron, 1989
[9] Microstructures Of TiN Films Grown By Various Physical Vapor-Deposition Techniques G. Hakansson, L. Hultman, J. E. Sundgren, J. E. Greene, W. D. Münz Surface & Coatings Technology, 1991, Vol. 48, No. 1, pp. 51-67
[10] A New Concept For Physical Vapor-Deposition Coating Combining the Methods of Arc Evaporation And Unbalanced-Magnetron Sputtering, W. D. Münz, F. Hauzer, D. Schulze, B. Buil; Surface & Coatings Technology, 1991, Vol. 49, No. 1-3, pp. 161-167
[11] A New Method For Hard Coatings—ABS (Arc Bond Sputtering) W. D. Münz, D. Schulze, F. Hauzer Surface & Coatings Technology, 1992, Vol. 50, No. 2, pp. 169-178
[12] Droplet Formation On Steel Substrates During Cathodic Steered Arc Metal Ion Etching, W. D. Münz, I. J. Smith, D. B. Lewis, S. Creasey; Vacuum, 1997, Vol. 48, No. 5, pp. 473-481
[13] Preferential erosive wear of droplet particles for cathodic arc/unbalanced magnetron sputtering CrN/NbN superlattice PVD coatings; H. W. Wang, M. M. Stack, S. B. Lyon, P. Hovsepian, W. D. Münz, Journal of Materials Science Letters. 15 Mar. 2001; vol. 20(6), pp. 547-50
[14] V. Kosnetsow, PCT application WO98/40532, EP 1038045
[15] V. Kosnetsow, K. Macak, J. M. Schneider, U. Helmersson, I. Petrov, Surf. Coat. Technol. 122 (2-3), (1999) p. 290
[16] A. P. Ehiasarian, R. New, W. D. Münz, L. Hultmann, U. Helmersson, V. Kosnetsow, Vacuum 65 (2002), p. 147
[17] Patent application, EP 1260603 A2
[18] U. Helmersson, S. Todorova, S. A. Barnett, J. E. -Sundgren, L. C. Markert, J. E. Greene, J. Appl. Phys. 62 (1987) p. 481

1. Method for multi-cathode PVD coating of substrates, comprising the following steps:
(a) pre-treating the substrate surface by high-power impulse magnetron cathode sputtering (HIPIMS),
(b) coating by means of unbalanced magnetron cathode sputtering (UBM),
(c) coating by means of HIPIMS, and
(d) repeating steps (b) and (c) one or more times.

2. Method according to claim 1, wherein said method further comprises carrying out step (a) with a cathode target comprising metal in a gas atmosphere at a pressure of less than or equal to 1·10⁻² mbar and with a substrate potential of −500 to −2000 V, with the substrate surface being etched and implanted with metal ions that have been positively charged one or more times.

3. Method according to claim 1, wherein step (a) further comprises introducing an inert gas or a mixture of inert gases, and the inert gas is selected from the group comprising argon, krypton, neon, xenon and helium.

4. Method according to claim 1, wherein said method further comprises carrying out step (a) with a cathode target comprising titanium, chromium, zirconium, niobium, tungsten, tantalum, molybdenum, aluminium or vanadium.

5. Method according to claim 1, wherein HIPIMS is carried out using pulse power densities on the cathode target of 800 to 3000 W·cm⁻², pulse lengths of 50 to 250 μs, pulse intervals of 20 to 200 ms, and a mean power density of 5 to 15 W·cm⁻².

6. Method according to claim 1, said method further comprising carrying out steps (b) and (c) simultaneously.

7. Method according to claim 1, wherein cathode targets in steps (b) and (c) comprise of different materials.

8. Method according to claim 6, wherein cathode targets in steps (b) and (c) comprise of different materials.

9. Method according to claim 1, said method further comprising a cathode target in step (b) comprising TiAl, TiAlY, CrAl, ZrAl, niobium or graphite.

10. Method according to claim 1, said method further comprising a cathode target in step (c) comprsing titanium, chromium, tungsten, tantalum or vanadium.

11. Method according to claim 1, said method further comprising applying a substrate potential of −50 to −200 V in steps (b) and (c).

12. Method according to claim 1, wherein steps (b) and (c) further comprise introducing an atmosphere comprising one or more inert gases, one or more reactive gases or a mixture of inert and reactive gases at a pressure of less than or equal to 1·10⁻² mbar.

13. Method according to claim 1, wherein steps (b) and (c) further comprise introduction an inert gas or a mixture of inert gases from the group comprising argon, krypton, neon, xenon and helium.

14. Method according to claim 1, wherein steps (b) and (c) comprise oxygen, nitrogen or acetylene is used as the reactive gas.

15. Method according to claim 1, wherein no droplets comprising melt erosion from the target material of the cathodes are produced in steps (a), (b) and (c).

16. Apparatus for multi-cathode PVD coating of substrates comprising one or more process chambers, with each process chamber being equipped with at least one HIPIMS cathode and at least one UBM cathode, with the substrates being fixed on substrate supports, with the number of substrate supports being equal to the number of process chambers, with the substrate support being positioned centrally between the HIPIMS and UBM cathodes in each process chamber, and with each substrate support being coupled to a rotary drive.

17. Apparatus according to claim 16, wherein the UBM cathodes are equipped with balanced permanent magnets and solenoid electromagnets, with the unbalance effect of the UBM plasma being produced solely by the magnetic field of the solenoid electromagnets.

18. Apparatus according to claim 16, wherein the balanced permanent magnets comprise NdFeB or SmCo.

19. Apparatus according to claim 16, wherein the HIPIMS and UBM cathodes in a process chamber are arranged in an alternating sequence thereby aligning their surfaces symmetrically with respect to the center lines of a regular polygon.

20. Apparatus according to claim 16, wherein two or more process chambers are arranged around a central chamber at an angular distance from one another of 360°/n where n=2 to 6, and are connected to the central chamber in a vacuum-tight manner.

21. Substrate with PVD coating, said PVD coating comprising an implantation layer, which is produced by HIPIMS in the substrate surface, and one or more double layers, which are deposited by means of UBM and HIPIMS.

22. Substrate according to claim 21, wherein a metal is implanted in the substrate.

23. Substrate according to claim 21, wherein the PVD coating is free of droplets from melt erosion from the target material of the cathodes.

24. Substrate according to claim 21, wherein the PVD coating has a plastic hardness of more than 40 GPa.

25. Substrate according to claim 21, wherein each double layer has an overall thickness of 2 to 20 nm and is comprised predominantly (greater than 95 by atomic percent) of materials from the group comprising metals, metal nitrides, metal oxynitrides, metal carbides, carbonitrides and carbon.

26. Substrate according to claim 25, wherein the double layer has an overall thickness of 3 to 5 nm.

27. Substrate according to claim 21, wherein the components of the double layer which are deposited by means of UBM and HIPIMS are comprised of different materials.

28. Substrate according to claim 21, wherein the component of each double layer which is deposited by means of UBM is comprised of the same material.

29. Substrate according to claim 21, wherein the component of each double layer which is deposited by means of HIPIMS is comprised of the same material.

30. Substrate according to claim 21, wherein the component of each double layer which is deposited by means of UBM is comprised of TiAlN, NbN or diamond-like carbon (DLC).

31. Substrate according to claim 21, wherein the component of each double layer which is deposited by means of HIPIMS is comprised of TiN, CrN, W, Ta, Ti, VN or CrN.

32. Substrate according to claim 21, wherein the layer system comprising HIPIMS implants and one or more double layers is a material combination from the group comprising (Ti) (TiAlN/TiN), (Cr) (TiAlN/CrN), (Ti) (NbN/TiN), (W) (DLC/W), (Ta) (DLC/Ta), (Ti) (DLC/Ti), (V) (TiAlN/VN) and (Cr) (NbN/CrN).
